(19) United States
(12) Patent Application Publication
(10) Pub. No.: US 2025/0029941 A1
(43) Pub. Date: Jan. 23, 2025

(54) SEMICONDUCTOR PACKAGE AND METHOD OF FABRICATING THE SAME

(71) Applicant: SAMSUNG ELECTRONICS CO., LTD., SUWON-SI (KR)

(72) Inventors: HYUNSU HWANG, Suwon-si (KR); UN-BYOUNG KANG, Suwon-si (KR); KUYOUNG KIM, Suwon-si (KR); JUMYONG PARK, Suwon-si (KR); DONGJOON OH, Suwon-si (KR); SANGHOO CHO, Suwon-si (KR)

(21) Appl. No.: 18/439,381

(22) Filed: Feb. 12, 2024

(30) Foreign Application Priority Data
Jul. 19, 2023 (KR) 10-2023-0094117
Aug. 18, 2023 (KR) 10-2023-0108352

(51) Int. Cl. H01L 23/00

(52) U.S. Cl. CPC H01L 24/05; H01L 24/03; H01L 24/16; H01L 2224/03005; H01L 2224/03826; H01L 2224/03827; H01L 2224/05017; H01L 2224/05073; H01L 2224/05147; H01L 2224/05557; H01L 2224/05573; H01L 2224/05655; H01L 2224/16227; H01L 2924/182

(57) ABSTRACT

Disclosed are semiconductor packages and their fabrication methods. The semiconductor package comprises a substrate, a seed layer on the substrate, and a wiring pad on the seed layer. The wiring pad includes a pad portion, and a capping layer on the seed layer and covering a top surface and a lateral surface of the pad portion. A bottom surface of the pad portion is in contact with a top surface of the seed layer. A width of the top surface of the pad portion is greater than a width of the bottom surface of the pad portion.

### CROSS-REFERENCE TO RELATED APPLICATIONS

This U.S. nonprovisional application claims priority under 35 U.S.C § 119 to Korean Patent Application No. 10-2023-0094117 filed on Jul. 19, 2023, and Korean Patent Application No. 10-2023-0108352 filed on Aug. 18, 2023, in the Korean Intellectual Property Office, the disclosures of which are both hereby incorporated by reference in their entirety.

### BACKGROUND

The present inventive concepts relate to a semiconductor package, and more particularly, to a semiconductor package including a wiring pad and a method of fabricating the same.

A semiconductor package may implement an integrated circuit chip for use in electronic products. A semiconductor package can be configured such that a semiconductor chip is mounted on a printed circuit board, and bonding wires or bumps are used to electrically connect the semiconductor chip to the printed circuit board. A substrate and a semiconductor chip may include pads for electrical connection. With the development of electronic industry, various studies of pads have been conducted to improve reliability and of semiconductor packages.

### SUMMARY

The embodiments of the present inventive concepts provide a semiconductor package having improved reliability and electrical properties and a method of fabricating the same.

The embodiments of the present inventive concepts can provide a semiconductor package having a reduced manufacturing cost due to process simplification in a method of fabricating the same.

According to various embodiments of the present inventive concepts, a semiconductor package may include a substrate; a seed layer on the substrate; and a wiring pad on the seed layer. The wiring pad may include: a pad portion; and a capping layer on the seed layer and the pad portion. A bottom surface of the pad portion may be in contact with a top surface of the seed layer. A width of a top surface of the pad portion may be greater than a width of the bottom surface of the pad portion.

According to various embodiments of the present inventive concepts, a semiconductor package may comprise: a redistribution substrate; a semiconductor chip on the redistribution substrate; and a chip pad on a bottom surface of the semiconductor chip. The chip pad may include a first pad portion and a first capping layer that covers the first pad portion. A bottom surface of the chip pad may be in contact with the bottom surface of the semiconductor chip. A width of the bottom surface of the chip pad may be less than a width of a top surface of the chip pad.

According to various embodiments of the present inventive concepts, a method of fabricating a semiconductor package may comprise: forming a seed layer on a substrate; forming on the seed layer a resist layer having an opening that exposes a top surface of the seed layer; forming a resist pattern by etching a lateral surface of the resist layer exposed by the opening, wherein a width at an upper portion of the resist pattern is less than a width at a lower portion of the resist pattern; forming a plurality of spacer patterns on a lateral surface of the resist pattern exposed by the opening, wherein the spacer patterns expose a central portion of the top surface of the seed layer; forming a pad portion on the exposed central portion of the seed layer between an adjacent pair of the plurality of spacer patterns, the pad portion filling a portion of the opening; removing the spacer patterns to form a through hole that exposes a lateral surface of the pad portion and a peripheral portion of the top surface of the seed layer; and forming a capping layer that fills the through hole and covers a top surface and the lateral surface of the pad portion.

### BRIEF DESCRIPTION OF DRAWINGS

FIGS. 1A to 1C illustrate conceptual diagrams showing a wiring pad of a semiconductor package, according to various embodiments of the present inventive concepts.

FIGS. 2 and 8 illustrate conceptual diagrams showing a method of fabricating a wiring pad of a semiconductor package, according to various embodiments of the present inventive concepts.

FIG. 9 illustrates a cross-sectional view showing a semiconductor package, according to various embodiments of the present inventive concepts.

FIG. 10 illustrates an enlarged view showing section A of FIG. 9.

### DETAILED DESCRIPTION OF EMBODIMENTS

Principles and embodiments of the present inventive concepts will now be described in detail with reference to the accompanying drawings to aid in clearly explaining the present inventive concepts. In this description, like reference numerals indicate like components.

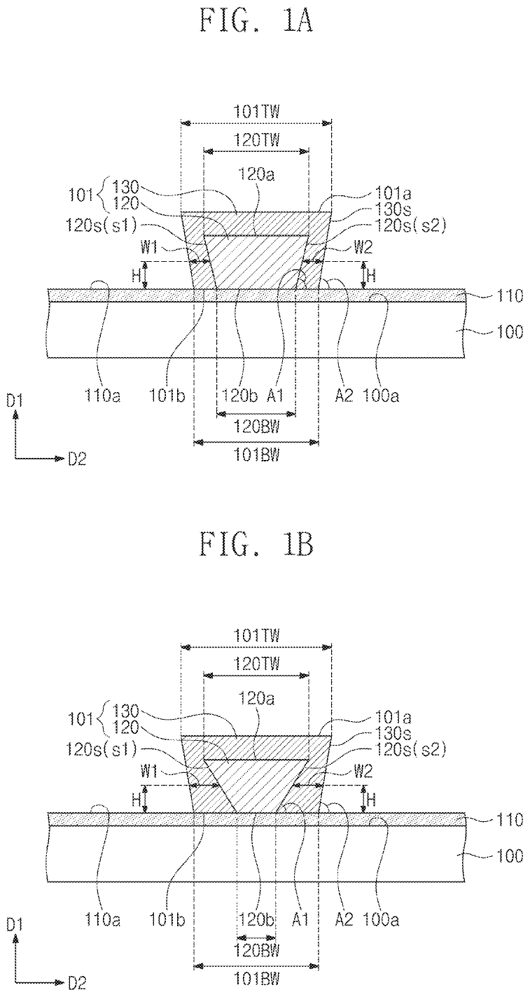

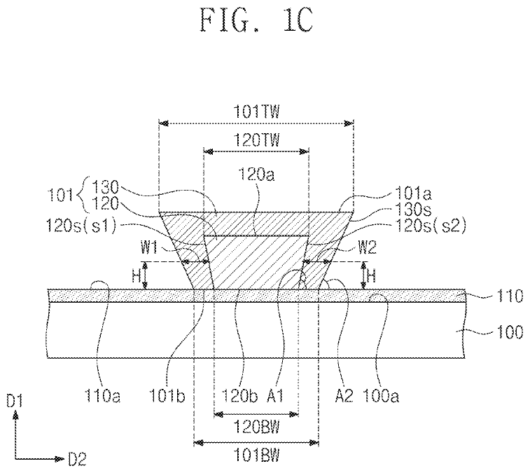

FIGS. 1A to 1C illustrate conceptual diagrams showing a wiring pad of a semiconductor package, according to various embodiments of the present inventive concepts.

Referring to FIGS. 1A to 1C, a semiconductor package may include a substrate 100 and a seed layer 110 disposed on the substrate 100. The substrate 100 may be a semiconductor substrate, such as a silicon substrate, a germanium substrate, or a silicon-germanium substrate. The seed layer 110 may include, for example, copper (Cu). A wiring pad 101 may be disposed on the seed layer 110. The wiring pad 101 may include a pad portion 120 and a capping layer 130. A bottom surface 101b of the wiring pad 101 may be in contact with a top surface 110a of the seed layer 110.

In various embodiments, the pad portion 120 may have a top surface 120a and a bottom surface 120b that are opposite to each other in a first direction D1, where the first direction D1 is perpendicular to a top surface 100a of the substrate 100. The bottom surface 120b of the pad portion 120 may be in contact with the top surface 110a of the seed layer 110. The pad portion 120 may have a width in a second direction D2 parallel to the top surface 100a of the substrate 100, where the first direction D1 may be called a vertical direction, and the second direction D2 may be called a horizontal direction. A width 120TW in the horizontal direction D2 of the top surface 120a of the pad portion 120 may be greater than a width 120BW in the horizontal direction D2 of the bottom surface 120b of the pad portion 120. The pad portion 120 may include, for example, copper (Cu).

In various embodiments, the capping layer 130 may cover the top surface 120a and a lateral surface 120s of the pad portion 120. The capping layer 130 may serve to prevent oxidation of the pad portion 120. The capping layer 130 may be disposed on the seed layer 110, where a portion of the capping layer 130 on the lateral surface 120s can adjoin the top surface 110a of the seed layer 110, and form a portion of the bottom surface 101b of the pad portion 120. The lateral surface 120s of the pad portion 120 may extend from the top surface 120a of the pad portion 120 to the top surface 110a of the seed layer 110. The lateral surface 120s of the pad portion 120 may have a first lateral surface s1 and a second lateral surface s2 that are opposite to each other with the pad portion 120 interposed between the first lateral surface s1 and the second lateral surface s2. The capping layer 130 may have a first width W1 in the horizontal direction D2 on the first lateral surface s1 of the pad portion 120, and the capping layer 130 may have a second width W2 in the horizontal direction D2 on the second lateral surface s2 of the pad portion 120. The first width W1 and the second width W2 may be the same at the same height H from the top surface 110a of the seed layer 110. The capping layer 130 may have a symmetric structure, for example, a vertical symmetric structure along a normal line to the top surface 100a of the substrate 100, where a vertical plane can divide the capping layer 130 and pad portion 120 through the center. The capping layer 130 may include, for example, nickel (Ni).

In various embodiments, the lateral surface 120s of the pad portion 120 may be inclined at a first angle A1 with respect to the top surface 110a of the seed layer 110, where the first angle A1 may be an acute angle. For example, the first angle A1 may range from about 45 degrees to about 90 degrees. The capping layer 130 may have an inner lateral surface in contact with the lateral surface 120s of the pad portion 120 and an outer lateral surface 130s opposite to the inner lateral surface with a thickness of the capping layer therebetween. The outer lateral surface 130s of the capping layer 130 may be inclined at a second angle A2 with respect to the top surface 110a of the seed layer 110, where the second angle A2 may be an acute angle. For example, the second angle A2 may range from about 45 degrees to about 90 degrees, where the first angle A1 and the second angle A2 may be different angles.

According to various embodiments of the present inventive concepts, as shown in FIGS. 1A to 1C, the first angle A1 and the second angle A2 may be the same or different from each other. Referring to FIG. 1A, the first angle A1 and the second angle A2 may be the same as each other. A slope of the lateral surface 120s of the pad portion 120 with respect to the top surface 110a of the seed layer 110 may be the same as a slope of the outer lateral surface 130s of the capping layer 130 with respect to the top surface 110a of the seed layer 110. The thickness of the capping layer 130 on the sidewall of the pad portion 120 may thereby be consistent. Referring to FIG. 1B, the first angle A1 may be less than the second angle A2. A slope of the lateral surface 120s of the pad portion 120 with respect to the top surface 110a of the seed layer 110 may be greater than a slope of the outer lateral surface 130s of the capping layer 130 with respect to the top surface 110a of the seed layer 110. The thickness of the capping layer 130 on the sidewall of the pad portion 120 may thereby be greater closer to the seed layer 110 and less proximal towards the top surface 110a of the seed layer 110. Referring to FIG. 1C, the first angle A1 may be greater than the second angle A2. A slope of the lateral surface 120s of the pad portion 120 with respect to the top surface 110a of the seed layer 110 may be less than a slope of the outer lateral surface 130s of the capping layer 130 with respect to the top surface 110a of the seed layer 110. The thickness of the capping layer 130 on the sidewall of the pad portion 120 may thereby be less closer to the seed layer 110 and greater proximal towards the top surface 110a of the seed layer 110. The first angle A1 and the second angle A2 may be independent of each other, and the capping layer 130 and the pad portion 120 may have independent profiles of each other.

In various embodiments, the wiring pad 101 including the pad portion 120 and the capping layer 130 may have a width in the horizontal direction D2. A width 101TW of the top surface 101a of the wiring pad 101 may be greater than a width 101BW of the bottom surface 101b of the wiring pad 101.

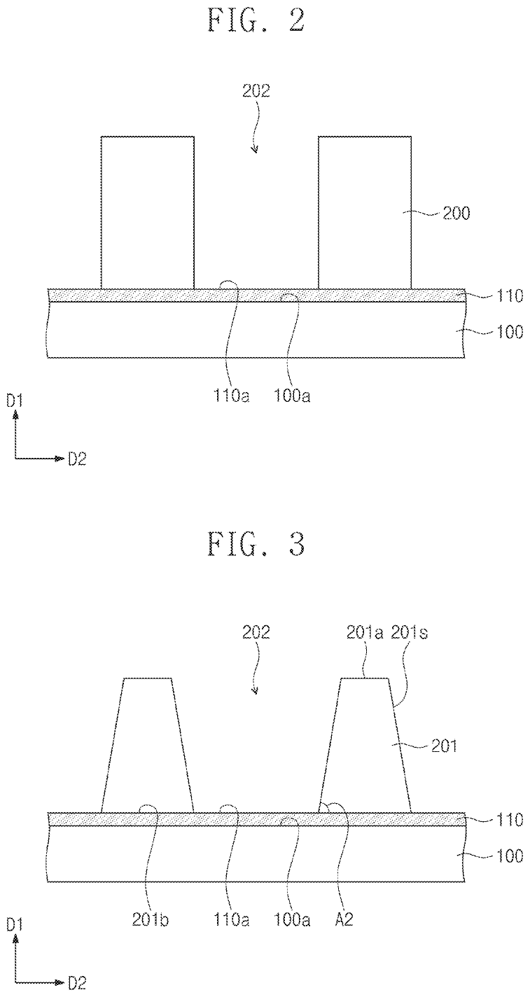

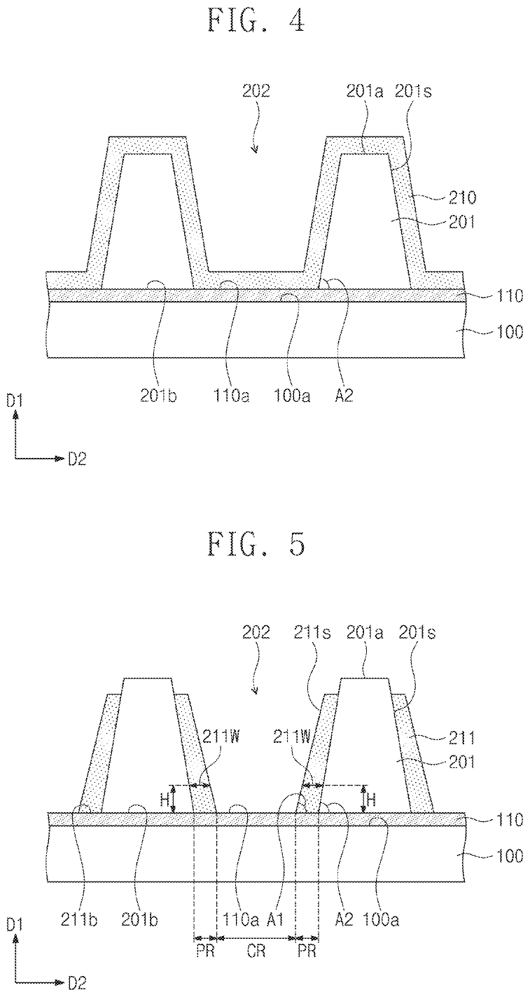

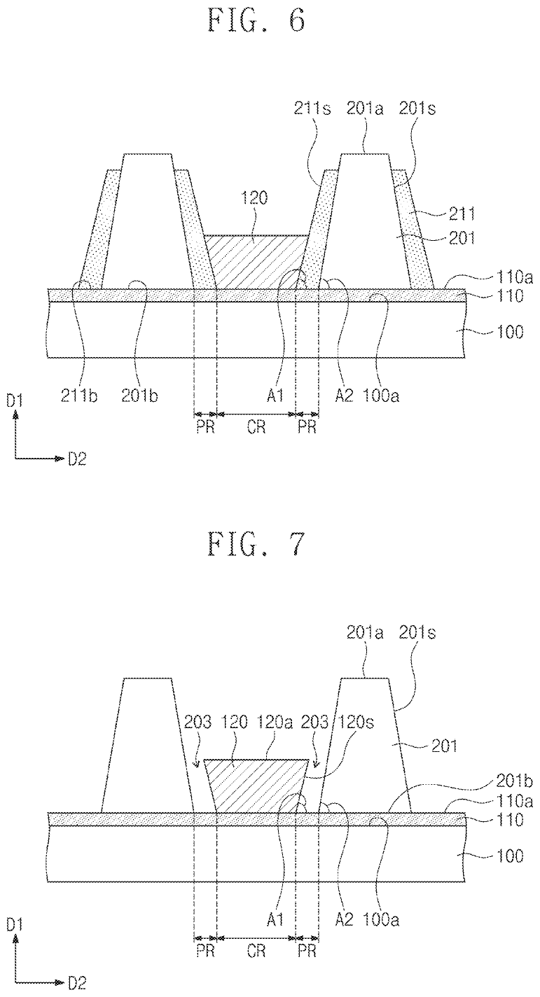

FIGS. 2 to 8 illustrate conceptual diagrams showing a method of fabricating a wiring pad of a semiconductor package according to various embodiments of the present inventive concepts. For brevity of description, omission may be made to avoid a discussion of those aspects previously discussed with reference to FIGS. 1A to 1C.

Referring to FIG. 2, a substrate 100 may be provided, and a seed layer 110 may be formed on the substrate 100. A resist layer 200 having an opening 202 formed therein may be formed on the seed layer 110. The opening 202 may expose a top surface 110a of the seed layer 110. The resist layer 200 may be a photoresist for a photolithography process. For example, the resist layer 200 may be a compound formed of C, H, and O. A material that constitutes the resist layer 200 may be expressed by CxHyOz (where, each of x, y, and z is an integer).

Referring to FIG. 3, a lateral surface of the resist layer 200 exposed by the opening 202 may be etched to form a resist pattern 201. A width at an upper portion of the resist pattern 201 may be less than a width at a lower portion of the resist pattern 201. A lateral surface 201s of the resist pattern 201 may be inclined in a horizontal direction D2 with respect to a top surface 100a of the substrate 100 to form a tapered structure. The lateral surface 201s of the resist pattern 201 may be inclined at a second angle A2 with respect to a bottom surface 201b of the resist pattern 201. The second angle A2 may be substantially the same as the second angle A2 at which the outer lateral surface 130s of the capping layer 130 is inclined with respect to the top surface 110a of the seed layer 110 which is discussed with reference to FIGS. 1A to 1C.

In various embodiments, the etching of the lateral surface of the resist layer 200 may be achieved through a plasma etching process that uses O₂/CF₄/Ar plasma. In the etching process, O₂ may be used as a primary etching gas (e.g., a main etchant). A concentration of O₂ in the etching process may be adjusted to control how much the lateral surface of the resist layer 200 is etched. For example, when the etching gas has a high concentration of O₂, the second angle A2 may become small, and when the etching gas has a low concentration of O₂, the second angle A2 may become large. In addition, a concentration of CF₄ in the etching gas may be adjusted to control how much the lateral surface of the resist layer 200 is etched. For example, when CF₄ has a high concentration, carbon (C) may be deposited on an upper portion of the resist layer 200, and thus the second angle A2 may become large. The adjustment of concentrations of O₂ and CF₄ in the etching gas may control how much the lateral surface of the resist layer 200 is etched, and therefore it may be possible to adjust how much the lateral surface 201s of the resist pattern 201 is inclined with respect to a bottom surface 201b of the resist pattern 201.

Referring to FIG. 4, a spacer layer 210 may be formed to conformally cover a top surface 201a and the lateral surface 201s of the resist pattern 201. The spacer layer 210 may extend onto the top surface 110a of the seed layer 110, and may extend between adjacent resist patterns 201. The spacer layer 210 may be formed by using a film formation technique such as chemical vapor deposition (CVD), physical vapor deposition (PVD), or atomic layer deposition (ALD). According to an embodiment of the present inventive concepts, the spacer layer 210 may include silicon (Si). According to another embodiment of the present inventive concepts, the spacer layer 210 may include silicon oxide (e.g., SiO₂).

Referring to FIG. 5, spacer patterns 211 may be formed on the lateral surface 201s of the resist pattern 201, where a plurality of spacer patterns 211 may be formed on a lateral surfaces 201s of the resist pattern 201 exposed by the opening from the spacer layer 210. The formation of the spacer patterns 211 may be performed through a first etching process. The first etching process may include anisotropically etching the spacer layer 210. The anisotropic etching of the spacer layer 210 may be performed through a plasma anisotropic etching process. The spacer patterns 211 may remove at least a portion of the spacer layer 210 between adjacent resist pattern 201 to expose a central portion CR of the top surface 110a of the seed layer 110.

In various embodiments, the spacer patterns 211 may have widths 211W in the horizontal direction D2. The widths 211W of the spacer patterns 211 may be substantially the same along the vertical direction D1 at the same height H from the top surface 110a of the seed layer 110.

In various embodiments, the spacer patterns 211 may have lateral surfaces 211s exposed by the opening 202. The lateral surfaces 211s of the spacer patterns 211 may be inclined at a first angle A1 with respect to bottom surfaces 211b of the spacer patterns 211. The first angle A1 may be substantially the same as the first angle A1 at which the lateral surface 120s of the pad portion 120 is inclined with respect to the top surface 110a of the seed layer 110 which is discussed with reference to FIGS. 1A to 1C. The first angle A1 may be an acute angle, where for example, the first angle A1 may range from about 45 degrees to about 90 degrees. The second angle A2 and the first angle A1 may be different from each other.

Referring to FIG. 6, a pad portion 120 may be formed on the seed layer 110 between the spacer patterns 211, thereby filling a portion of the opening 202. The pad portion 120 can be formed on the exposed central portion CR of the seed layer 110 between an adjacent pair of the plurality of spacer patterns 211. The formation of the pad portion 120 may be achieved through an electroplating process in which the seed layer 110 is used as a seed. A top surface of the pad portion 120 may be below a portion of the spacer patterns 211, where a lower portion of the spacer patterns 211 may separate the pad portion 120 from the resist patterns 201, and an upper portion may extend above the top surface of the pad portion 120.

Referring to FIG. 7, the spacer patterns 211 may be removed, and thus a through hole 203 may be formed between the resist pattern 201 and the pad portion 120. The through hole 203 may expose the lateral surface 201s of the resist pattern 201, a lateral surface 120s of the pad portion 120, and a peripheral portion PR of the top surface 110a of the seed layer 110. A second etching process may be performed to remove the spacer patterns 211, where the second etching process may be a selective etching process. According to an embodiment, when the spacer patterns 211 include silicon (Si), the second etching process may include a plasma etching process that uses NF₃. According to another embodiment, when the spacer patterns 211 include silicon oxide (SiO₂), the second etching process may include wet etching that uses a phosphoric acid. The seed layer 110, the pad portion 120, and the resist pattern 201 may not be etched during the removal of the spacer patterns 211.

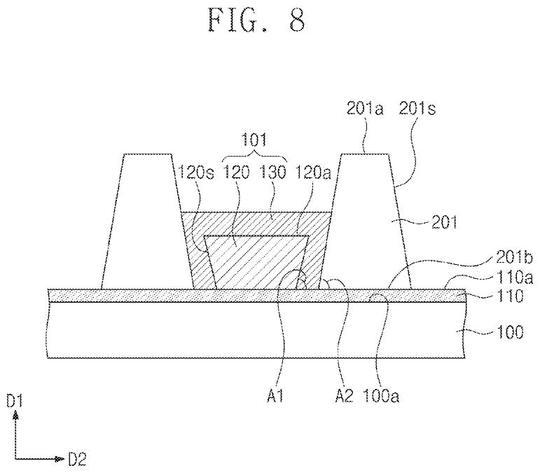

Referring to FIG. 8, a capping layer 130 may be formed to fill the through hole 203 and to cover a top surface 120ₐ and the lateral surface 120ₛ of the pad portion 120. The formation of the capping layer 130 may be performed through a film formation technique, such as chemical vapor deposition (CVD), physical vapor deposition (PVD), or atomic layer deposition (ALD), where the capping layer 130 may be formed in through hole 203. As discussed with reference to FIG. 5, as the widths 211W of the spacer patterns 211 are substantially the same at the same height H in the vertical direction D1 from the top surface 110a of the seed layer 110, the capping layer 130 may be formed to have a symmetric structure (e.g., a vertical symmetric structure along a normal line to the top surface 110a of the seed layer 110).

Referring back to FIGS. 1A to 1C, the resist patterns 201 may be removed. The removal of the resist patterns 201 may be performed by an ashing process and/or a strip process. The lateral surface 120s of the pad portion 120 may be inclined at a first angle A1 with respect to the top surface 110a of the seed layer 110. An outer lateral surface 130s of the capping layer 130 may be inclined at a second angle A2 with respect to the top surface 110a of the seed layer 110.

The pad portion 120 and the capping layer 130 may each be formed by an independent photolithography process. The two photolithography processes, however, may lead to difficulty in obtaining an overlay margin and uniformly controlling a thickness of the capping layer 130, such that the capping layer 130 may be formed with a relatively large thickness and an asymmetric structure, where the first width W1 and the second width W2 may be different. If the formation process of the capping layer 130 results in a relatively large thickness and an asymmetric structure, a wiring pad 101 may decrease in reliability and electrical properties.

According to principles and embodiments of the present inventive concepts, a photolithography process may be performed a single time to form the wiring pad 101, and the capping layer 130 may be formed to have a relatively small thickness and a symmetric structure. Therefore, a semiconductor package may include a wiring pad 101 having improved reliability and electrical properties. In addition, a simplification of fabrication of the wiring pad 101 may result in a reduction in manufacturing cost and an improvement in fabrication speed of a semiconductor package.

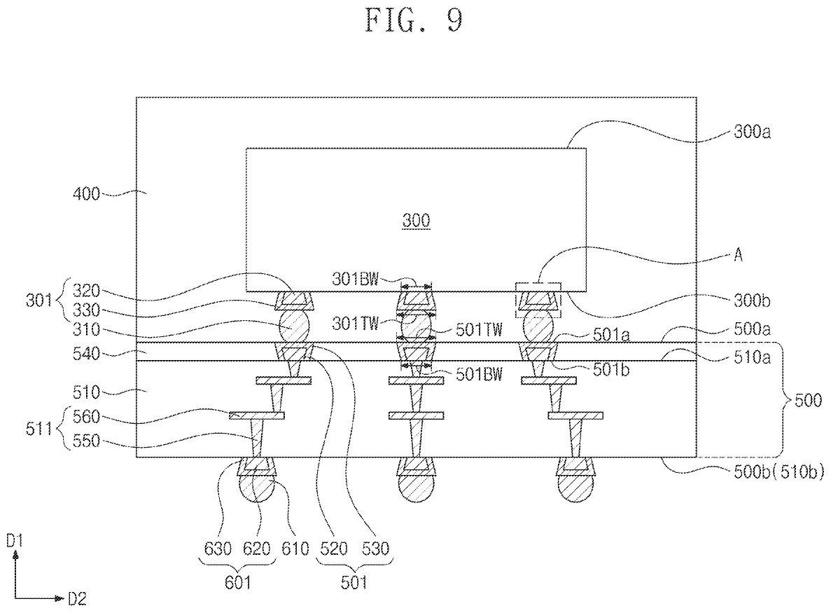

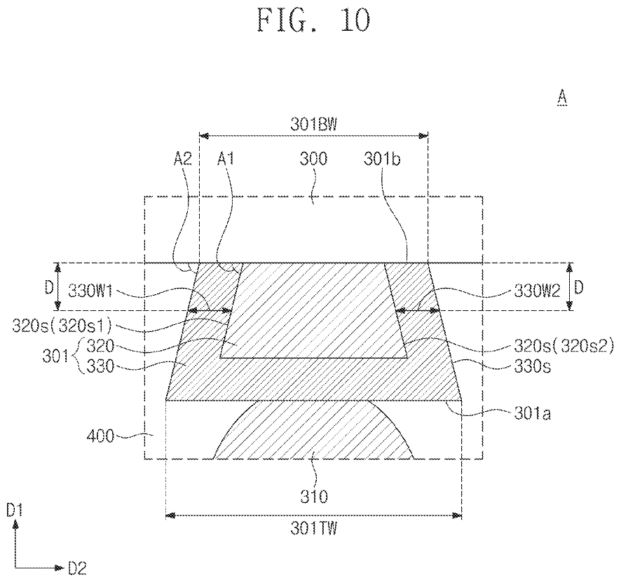

FIG. 9 illustrates a cross-sectional view showing a semiconductor package according to various embodiments of the present inventive concepts. FIG. 10 illustrates an enlarged view showing section A of FIG. 9. For brevity of description, omission may be made to avoid a discussion of the wiring pad of the semiconductor package discussed with reference to FIGS. 1A to 1C.

Referring to FIGS. 9 and 10, a semiconductor package may include a redistribution substrate 500 and a semiconductor chip 300 mounted on the redistribution substrate 500. When viewed in plan, the semiconductor chip 300 may be disposed on a central region of the redistribution substrate 500. The semiconductor chip 300 may be a memory chip, a logic chip, an application processor (AP) chip, or a system-on-chip (SOC).

In various embodiments, the semiconductor chip 300 may have a top surface 300a and a bottom surface 300b that are opposite to each other in a first direction D1 perpendicular to a top surface 500a of the redistribution substrate 500. A chip pad 301 may be disposed on the bottom surface 300b of the semiconductor chip 300. A bottom surface 301b of the chip pad 301 may be in contact with a bottom surface 300b of the semiconductor chip 300. The chip pad 301 may be electrically connected to integrated circuits of the semiconductor chip 300. The chip pad 301 may include a first pad portion 320 and a first capping layer 330. The first capping layer 330 may cover a top surface and a lateral surface 320s of the first pad portion 320. The first pad portion 320 may include, for example, copper (Cu). The first capping layer 330 may include, for example, nickel (Ni). The chip pad 301 may have a width in a second direction D2 parallel to the top surface 500a of the redistribution substrate 500. The first direction D1 may be referred to as a vertical direction, and the second direction D2 may be referred to as a horizontal direction. A width 301BW in the horizontal direction D2 of the bottom surface 301b of the chip pad 301 may be less than a width 301TW in the horizontal direction D2 of a top surface 301a of the chip pad 301.

In various embodiments, the lateral surface 320s of the first pad portion 320 may include a first lateral surface 320s1 and a second lateral surface 320s2 that are opposite to each other. The first capping layer 330 may have a first width 330W1 in the horizontal direction D2 on the first lateral surface 320s1 of the first pad portion 320. The first capping layer 330 may have a second width 330W2 in the horizontal direction D2 on the second lateral surface 320s2 of the first pad portion 320. The first width 330W1 and the second width 330W2 may be the same as each other at a distance D, along a direction opposite to the vertical direction D1, from the bottom surface 300b of the semiconductor chip 300. The first capping layer 330 may have a symmetric structure (e.g., a vertical symmetric structure along a normal line to the bottom surface 300b of the semiconductor chip 300).

In various embodiments, the lateral surface 320s of the first pad portion 320 may be inclined at a first angle A1 with respect to the bottom surface 300b of the semiconductor chip 300. The first angle A1 may be an acute angle, where for example, the first angle A1 may range from about 45 degrees to about 90 degrees. The first capping layer 330 may have an inner lateral surface in contact with the lateral surface 320s of the first pad portion 320 and an outer lateral surface 330s opposite to the inner lateral surface. The outer lateral surface 330s of the first capping layer 330 may be inclined at a second angle A2 with respect to the bottom surface 300b of the semiconductor chip 300. The second angle A2 may be an acute angle, where for example, the second angle A2 may range from about 45 degrees to about 90 degrees. According to various embodiments of the present inventive concepts, the chip pad 301 may be substantially the same as the wiring pad 101 discussed with reference to FIGS. 1A to 1C. As discussed with reference to FIGS. 1A to 1C, the first angle A1 and the second angle A2 may be different from each other. For example, the first angle A1 and the second angle A2 may be independent of each other, and the first capping layer 330 and the first pad portion 320 may have profiles that are independent of each other. The first angle and the second angle may each be in a range of about 45 degrees to about 90 degrees, where the first angle and the second angle may be different angles.

In various embodiments, the formation of the chip pad 301 may be substantially the same as the formation of the wiring pad 101 discussed with reference to FIGS. 2 to 8. For example, a photolithography process may be performed a single time to form the chip pad 301, and thus the first capping layer 330 may have a symmetric structure.

In various embodiments, the redistribution substrate 500 may include a dielectric layer 510, redistribution patterns 511, including redistribution vias 550, and redistribution pads 560 disposed in the dielectric layer 510, and a protection layer 540 disposed on the dielectric layer 510. The dielectric layer 510 may include one or more stacked dielectric layers. The number of the redistribution patterns 511 may be different from the number that are shown. The redistribution patterns 511 may include metal, such as copper, aluminum, titanium, or tungsten. The dielectric layer 510 may include, for example, a photosensitive dielectric material.

In various embodiments, the protection layer 540 may be formed on a top surface 500a of the dielectric layer 510. The protection layer 540 may include, for example, a dielectric polymer. A conductive pad 501 may be disposed in the protection layer 540. The conductive pad 501 may be formed on and electrically connected to the redistribution patterns 511. A bottom surface 501b of the conductive pad 501 may be in contact with the top surface 510a of the dielectric layer 510. A top surface 501a of the conductive pad 501 may be coplanar with a top surface of the protection layer 540, and/or the top surface 500a of the redistribution substrate 500. The conductive pad 501 may include a second pad portion 520 and a second capping layer 530. The conductive pad 501 may have a width in the horizontal direction D2. A width 501TW of the top surface 501a of the conductive pad 501 may be greater than a width 501BW of the bottom surface 501b of the conductive pad 501.

In various embodiments, the conductive pad 501 may be substantially the same as the wiring pad 101 discussed with reference to FIGS. 1A to 1C, and the formation of the conductive pad 501 may be substantially the same as the formation of the wiring pad 101 discussed with reference to FIGS. 2 to 8.

In various embodiments, a connection terminal 310 may be disposed between the chip pad 301 and the conductive pad 501. The connection terminal 310 may electrically connect the conductive pad 501 and the chip pad 301 to each other. The semiconductor chip 300 may be electrically connected through the connection terminal 310 to the redistribution substrate 500. The connection terminal 310 may include a conductive material, and may have a shape selected from solder-ball shapes, bump shapes, and pillar shapes. The connection terminal 310 may include metal (e.g., copper).

In various embodiments, a molding layer 400 may be disposed on the redistribution substrate 500. The molding layer 400 may cover the semiconductor chip 300. The molding layer 400 may extend between the semiconductor chip 300 and the protection layer 540 of the redistribution substrate 500 to encapsulate the chip pad 301 and the connection terminal 310. The molding layer 400 may include a dielectric polymer, such as an epoxy-based molding compound.

The chip pad 301 can have a profile in which the width 301TW of the top surface 301a is greater than the width 301BW of the bottom surface 301b, and the chip pad 301 may have an increased adhesion force. For example, the second angle A2 may have an acute angle, and thus a space between neighboring chip pads 301 may increase with decreasing distance from the bottom surface 300b of the semiconductor chip 300. Therefore, the molding layer 400 may easily fill the space between neighboring chip pads 301, and as a result, there may be an increase in bonding force between the chip pad 301 and the molding layer 400.

In various embodiments, a terminal pad 601 may be disposed on the bottom surface 500b of the redistribution substrate 500. The terminal pad 601 may include a third pad portion 620 and a third capping layer 630. When viewed in a plan view, the terminal pad 601 may not overlap any of the chip pad 301 and the conductive pad 501. The terminal pad 601 may be substantially the same as the wiring pad 101 discussed with reference to FIGS. 1A to 1C, and the formation of the terminal pad 601 may be substantially the same as the formation of the wiring pad 101 discussed with reference to FIGS. 2 to 8. The third pad portion 620 may be substantially the same as the pad portion 120, and the third capping layer 630 may be substantially the same as the capping layer 130.

In various embodiments, an external coupling terminal 610 may be disposed on a bottom surface of the terminal pad 601. The external coupling terminal 610 may be electrically connected to the chip pad 301 through the terminal pad 601, the redistribution patterns 511, and the connection terminal 310. The external coupling terminal 610 may include a conductive material, and may have a shape selected from solder-ball shapes, bump shapes, and pillar shapes. The external coupling terminal 610 may include metal (e.g., copper).

A semiconductor package according to the present inventive concepts may include a wiring pad that is formed by a photolithography process performed a single time. The wiring pad may have a symmetric structure, and thus a semiconductor package including the wiring pad may demonstrate an improvement in reliability and electrical properties. In addition, the fabrication process for forming the wiring pad may be simplified to reduce manufacturing cost for fabricating the semiconductor package. Moreover, a profile of the wiring pad may be adjusted to increase an adhesion force between the wiring pad and a molding layer that surrounds the wiring pad.

The aforementioned description provides various embodiments for explaining the present inventive concepts. Therefore, the present inventive concepts are not limited to the embodiments described above, and it will be understood by one of ordinary skill in the art that variations in form and detail may be made therein without departing from the spirit and scope of the present inventive concepts.

What is claimed is:

1. A semiconductor package, comprising:
a substrate;
a seed layer on the substrate; and
a wiring pad on the seed layer,
wherein the wiring pad includes:
a pad portion; and
a capping layer on the seed layer and covering the pad portion,
wherein a bottom surface of the pad portion is in contact with a top surface of the seed layer, and
wherein a width of a top surface of the pad portion is greater than a width of the bottom surface of the pad portion.

2. The semiconductor package of claim 1, wherein
the capping layer is in contact with the top surface of the seed layer, and
a width of a top surface of the wiring pad is greater than a width of a bottom surface of the wiring pad.

3. The semiconductor package of claim 1,
wherein the pad portion has a first lateral surface and a second lateral surface that are opposite to each other,
wherein the capping layer has:
a first width in a horizontal direction on the first lateral surface of the pad portion, the horizontal direction being parallel to a top surface of the substrate; and
a second width in the horizontal direction on the second lateral surface of the pad portion,
wherein the first width and the second width are the same as each other at the same height in a vertical direction from the top surface of the substrate, the vertical direction being perpendicular to the top surface of the substrate.

4. The semiconductor package of claim 1, wherein a lateral surface of the pad portion is inclined at a first angle with respect to the top surface of the seed layer,
wherein the first angle is an acute angle.

5. The semiconductor package of claim 4,
wherein the capping layer has:
an inner lateral surface in contact with the lateral surface of the pad portion; and
an outer lateral surface opposite the inner lateral surface with a thickness of the capping layer therebetween,
wherein the outer lateral surface of the capping layer is inclined at a second angle with respect to the top surface of the seed layer,
wherein the second angle is an acute angle.

6. The semiconductor package of claim 5, wherein the first angle and the second angle are each in a range of about 45 degrees to about 90 degrees.

7. The semiconductor package of claim 5, wherein the first angle and the second angle are different from each other.

8. A semiconductor package, comprising:
a redistribution substrate;
a semiconductor chip on the redistribution substrate; and
a chip pad on a bottom surface of the semiconductor chip,
wherein the chip pad includes:
a first pad portion; and
a first capping layer that covers the first pad portion,
wherein a bottom surface of the chip pad is in contact with the bottom surface of the semiconductor chip, and
wherein a width of the bottom surface of the chip pad is less than a width of a top surface of the chip pad.

9. The semiconductor package of claim 8,
wherein the first pad portion has a first lateral surface and a second lateral surface that are opposite to each other,
wherein the first capping layer has:
a first width in a horizontal direction on the first lateral surface of the first pad portion, the horizontal direction being parallel to a top surface of the redistribution substrate; and
a second width in the horizontal direction on the second lateral surface of the first pad portion,
wherein the first width and the second width are the same as each other at the same distance in a direction from the bottom surface of the semiconductor chip, the direction being opposite to a vertical direction perpendicular to the top surface of the redistribution substrate.

10. The semiconductor package of claim 8,
wherein a lateral surface of the first pad portion is inclined at a first angle with respect to the bottom surface of the semiconductor chip,
wherein the first capping layer includes:
an inner lateral surface in contact with the lateral surface of the first pad portion; and
an outer lateral surface opposite the inner lateral surface with a thickness of the first capping layer therebetween,
wherein the outer lateral surface of the first capping layer is inclined at a second angle with respect to the bottom surface of the semiconductor chip,
wherein the first angle and the second angle are each an acute angle.

11. The semiconductor package of claim 10, wherein the first angle and the second angle are each in a range of about 45 degrees to about 90 degrees.

12. The semiconductor package of claim 10, wherein the first angle and the second angle are different from each other.

13. The semiconductor package of claim 8,
wherein the redistribution substrate includes a dielectric layer and a protection layer,
wherein the semiconductor package further comprises a conductive pad,
wherein the conductive pad includes:
a second pad portion; and
a second capping layer that covers a top surface and a lateral surface of the second pad portion,
wherein a bottom surface of the conductive pad is in contact with a top surface of the dielectric layer of the redistribution substrate, and
wherein a width of a top surface of the conductive pad is greater than a width of the bottom surface of the conductive pad.

14. The semiconductor package of claim 13, further comprising a connection terminal that electrically connects the chip pad to the conductive pad.

15. The semiconductor package of claim 14, further comprising a molding layer on the redistribution substrate and covering the semiconductor chip,
wherein the molding layer extends between the semiconductor chip and the protection layer of the redistribution substrate to encapsulate the chip pad and the connection terminal.

16. A method of fabricating a semiconductor package, the method comprising:
forming a seed layer on a substrate;
forming on the seed layer a resist layer having an opening that exposes a top surface of the seed layer;
forming a resist pattern by etching a lateral surface of the resist layer exposed by the opening, wherein a width at an upper portion of the resist pattern is less than a width at a lower portion of the resist pattern;
forming a plurality of spacer patterns on a lateral surface of the resist pattern exposed by the opening, wherein the spacer patterns expose a central portion of the top surface of the seed layer;
forming a pad portion on the exposed central portion of the seed layer between an adjacent pair of the plurality of spacer patterns, the pad portion filling a portion of the opening;
removing the spacer patterns to form a through hole that exposes a lateral surface of the pad portion and a peripheral portion of the top surface of the seed layer; and
forming a capping layer that fills the through hole and covers a top surface and the lateral surface of the pad portion.

17. The method of claim 16, wherein the plurality of spacer patterns includes silicon (Si),
wherein removing the plurality of spacer patterns includes using a plasma etching process utilizing NF₃.

18. The method of claim 16, wherein the plurality of spacer patterns includes silicon oxide, and
wherein removing the plurality of spacer patterns includes using a wet etching process.

19. The method of claim 16, wherein the plurality of spacer patterns have widths in a horizontal direction parallel to a top surface of the substrate, wherein the widths are the same at the same height in a vertical direction from the top surface of the seed layer, the vertical direction being perpendicular to the top surface of the substrate.

20. The method of claim 16, wherein
lateral surfaces of the plurality of spacer patterns exposed by the opening are inclined at a first angle with bottom surfaces of the spacer patterns,
the lateral surface of the resist pattern is inclined at a second angle with a bottom surface of the resist pattern, and
the first angle and the second angle are an acute angle.
